(19) United States
(12) Patent Application Publication
(10) Pub. No.: US 2022/0339754 A1
(43) Pub. Date: Oct. 27, 2022

(54) POLISHING METHOD

(71) Applicant: DISCO CORPORATION, Tokyo (JP)

(72) Inventors: Naruto FUWA, Tokyo (JP); Ryohei YOKOTA, Tokyo (JP)

(21) Appl. No.: 17/395,144

(22) Filed: Aug. 5, 2021

(30) Foreign Application Priority Data
Apr. 22, 2021 (JP) 2021-072315

(51) Int. Cl. B24B 37/10; B24B 37/30; B24B 9/06

(52) U.S. Cl. CPC B24B 37/10; B24B 37/30; B24B 9/065

(57) ABSTRACT

A polishing method for polishing a wafer by use of a polishing unit having a spindle with a polishing tool, the polishing tool having a disk-shaped base and an annular polishing layer that is fixed to one surface of the base and that includes an opening being located at a central portion in a diameter direction of the base and having a predetermined diameter, a maximum width of an effective polishing region of the polishing layer in a radial direction of the base being smaller than the radius of the wafer and the radius of the wafer being smaller than the diameter of the opening, the method includes polishing the wafer in such a manner that a part of a peripheral edge of the wafer protrudes from a periphery of the polishing layer and that the center of the wafer is located in the opening section of the polishing layer.

### BACKGROUND OF THE INVENTION

### Field of the Invention

The present invention relates to a polishing method for polishing a wafer and a polishing tool used when polishing a wafer.

### Description of the Related Art

Semiconductor device chips are mounted on electronics such as mobile phones and personal computers. The semiconductor device chips are manufactured by processing a semiconductor wafer whose front surface is formed with a plurality of streets in a grid pattern, with a device such as an integrated circuit (IC) or large scale integration (LSI) formed in each of regions partitioned by the streets. Specifically, a back surface side of the semiconductor wafer is ground to thin the wafer, and thereafter, the semiconductor wafer is cut along the streets, to manufacture the semiconductor device chips. For grinding the semiconductor wafer, a grinding apparatus is used. For example, the back surface side of the semiconductor wafer is sequentially subjected to rough grinding and finish grinding, whereby the semiconductor wafer is thinned to a predetermined thickness (see, for example, Japanese Patent Laid-open No. 2000-288881).

However, by the grinding, grinding marks (or saw marks) are formed on the work surface. If the semiconductor wafer is divided into semiconductor device chips in a state in which the grinding marks are left on the work surface, the die strength of the semiconductor device chips is lowered as compared to the case where the grinding marks are absent. In view of this, chemical mechanical polishing (CMP) of polishing the back surface side of the semiconductor wafer and removing the saw marks is conducted after the grinding (see, for example, Japanese Patent Laid-open No. Hei 8-99265). A polishing apparatus used in the CMP has a disk-shaped chuck table.

The chuck table has a holding surface for holding the semiconductor wafer under suction. On an upper side of the chuck table, a polishing unit having a cylindrical spindle is disposed. The spindle is disposed substantially in parallel to the vertical direction. A disk-shaped polishing wheel is mounted, for example, to a lower end portion of the spindle through a wheel mount (see, for example, Japanese Patent No. 5405979). The polishing wheel has a wheel base formed with a hole penetrating from a central portion of an upper surface to a central portion of a lower surface. On one surface of the wheel base, a plurality of segment polishing pads are arranged in an annular pattern around the hole. Each of the segment polishing pads has a polishing region having a width smaller than a diameter of the wafer held by the chuck table but larger than a radius of the wafer, in a radial direction of the wheel base.

### SUMMARY OF THE INVENTION

However, in the case of polishing the wafer by use of the polishing wheel, the vicinity of the center of the work surface of the wafer may be excessively polished, resulting in generation of a recess in the vicinity of the center of the wafer. The present invention has been made in consideration of such a problem, and it is an object of the present invention to restrain generation of a recess in the vicinity of the center of the work surface of the wafer.

In accordance with an aspect of the present invention, there is provided a polishing method for polishing a wafer by use of a polishing apparatus including a chuck table rotatable in a state of holding the wafer and a polishing unit having a spindle to which a polishing tool for polishing the wafer held by a holding surface of the chuck table is mounted, the polishing tool having a disk-shaped base and an annular polishing layer that is fixed to one surface of the base and that has an opening section being located at a central portion in a diameter direction of the base and having a predetermined diameter, a maximum width of an effective polishing region of the polishing layer in a radial direction of the base being smaller than a radius of the wafer and the radius of the wafer being smaller than the diameter of the opening section, the polishing method including a holding step of holding the wafer by the holding surface; and a polishing step of polishing the wafer while rotating the polishing tool around the spindle in a state in which the wafer and the polishing tool are positioned in such a manner that a part of a peripheral edge of the wafer protrudes from a periphery of the polishing layer and that the center of the wafer is located at the opening section of the polishing layer.

Preferably, in the polishing step, the polishing tool and the wafer are moved relative to each other along a diameter direction of the polishing tool that passes through a center of one surface of the wafer.

In accordance with another aspect of the present invention, there is provided a polishing tool to be used when polishing a wafer, the polishing tool including a disk-shaped base; and an annular polishing layer that is fixed to one surface of the base and that has an opening section being located at a central portion in a diameter direction of the base and having a predetermined diameter. In the polishing tool, a maximum width of an effective polishing region of the polishing layer in a radial direction of the base is smaller than the diameter of the opening section.

In the polishing method according to one mode of the present invention, used is the polishing tool having the disk-shaped base and the annular polishing layer that is fixed to one surface of the base and that includes the opening section being located at a central portion in the diameter direction of the base and having a predetermined diameter, in which the maximum width of the effective polishing region of the polishing layer in the radial direction of the base is smaller than the radius of the wafer and the radius of the wafer is smaller than the diameter of the opening section. In the polishing step, the wafer is polished in a state in which the wafer and the polishing tool are positioned such that a part of the peripheral edge of the wafer protrudes from the periphery of the polishing layer and the center of the wafer is located at the opening section of the polishing layer. Thus, generation of a recess in the vicinity of the center of the work surface can be restrained.

The polishing tool according to another mode of the present invention includes the disk-shaped base and the annular polishing layer which is fixed to one surface of the base and includes the opening section being located at a central portion in the diameter direction of the base and having a predetermined diameter. In the polishing tool, the maximum width of the effective polishing region of the polishing layer in the radial direction of the base is smaller than the diameter of the opening section. Thus, in the case of polishing a wafer having a radius smaller than the diameter of the opening section, generation of a recess in the vicinity of the center of the work surface can be restrained.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a polishing apparatus;

FIG. 2 is a bottom view of a polishing tool;

FIG. 3 is a flow chart of a polishing method;

FIG. 4 is a diagram depicting a manner of polishing a wafer;

FIG. 5A is a general bottom view depicting a positional relation of the polishing tool and the wafer in a first embodiment;

FIG. 5B is a general sectional view depicting the wafer polished in a state of being disposed at a front position;

FIG. 5C is a general sectional view depicting the wafer polished in a state of being disposed at a rear position;

FIG. 6 is a graph depicting a removal amount of the wafer by polishing;

FIG. 7A is a general bottom view depicting the positional relation of the polishing tool and the wafer in a comparative example;

FIG. 7B is a general sectional view depicting the wafer polished in the state of being disposed at a front position;

FIG. 7C is a general sectional view depicting the wafer polished in the state of being disposed at a rear position; and

FIG. 8 is a bottom view of a polishing tool according to a second embodiment.

### DETAILED DESCRIPTION OF THE PREFERRED EMBODIMENTS

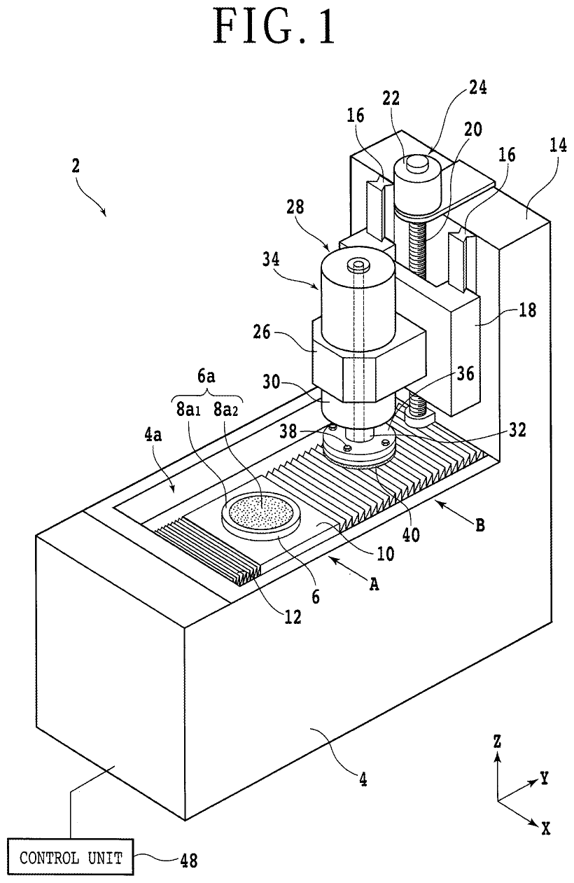

An embodiment according to one mode of the present invention will be described below referring to the attached drawings. FIG. 1 is a perspective view of a polishing apparatus 2. Note that an X-axis direction, a Y-axis direction, and a Z-axis direction (vertical direction, processing feeding direction) are orthogonal to one another. The polishing apparatus 2 has a base 4 which supports constituent elements. An upper portion of the base 4 is formed with an opening 4a whose longitudinal direction is in the Y-axis direction. A disk-shaped chuck table 6 is disposed in the opening 4a.

The chuck table 6 has a metallic frame body and a porous plate formed of porous ceramic. An upper surface 8a₁ of the frame body and an upper surface 8a₂ of a porous plate are flush with each other, and constitute a substantially flat holding surface 6a. The frame body is formed with a predetermined flow channel (not illustrated), and a suction source (not illustrated) such as an ejector is connected to the flow channel. A negative pressure generated in the suction source is transmitted through the predetermined flow channel to the upper surface 8a₂ of the porous plate.

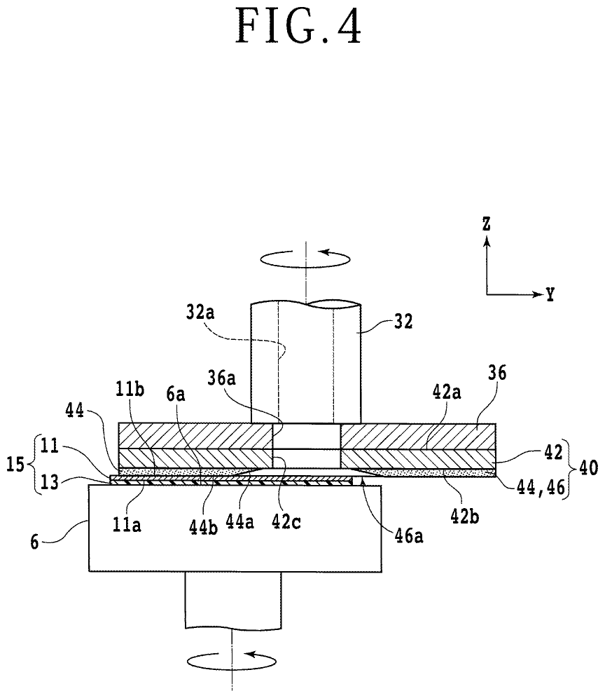

A front surface 11a side of a wafer 11 (see FIG. 4) having a diameter substantially equal to that of the upper surface 8a₂ of the porous plate is held under suction on the holding surface 6a. The diameter of the wafer 11 in the present embodiment is equal to or larger than the diameter of the upper surface 8a₂ of the porous plate but is smaller than the outside diameter of the upper surface 8a₁ of the frame body. The wafer 11 is a disk-shaped semiconductor wafer formed of silicon or the like, and a plurality of streets (not illustrated) are set in a grid pattern on the front surface 11a side. A device (not illustrated) such as an IC or LSI is formed in each of regions partitioned by the streets. At the time of polishing, the front surface 11a side faces the holding surface 6a, and a back surface 11b side is exposed on the upper side, so that, for reducing damage to the devices, a resin-made protective tape 13 substantially equal in diameter to the wafer 11 is attached to the front surface 11a side, to form a wafer unit 15 (see FIG. 4).

A rotational drive source (not illustrated) such as a motor is provided at a lower portion of the chuck table 6, and an output shaft of the rotational drive source is connected to a lower surface side of the chuck table 6. The chuck table 6 is rotatable around the output shaft. The rotational drive source is supported by a Y-axis moving plate (not illustrated). The Y-axis moving plate is slidably attached to a pair of guide rails (not illustrated) disposed substantially in parallel to the Y-axis direction. A nut section (not illustrated) is provided on a lower surface side of the Y-axis moving plate. A ball screw (not illustrated) disposed substantially in parallel to the Y-axis direction is rotatably connected to the nut section. A drive source (not illustrated) such as a pulse motor is connected to one end portion of the ball screw.

The Y-axis moving plate, the pair of guide rails, the ball screw, the drive source, and the like constitute a Y-axis direction moving mechanism for moving the chuck table 6 and the rotational drive source in the Y-axis direction. As depicted in FIG. 1, a rectangular table base 10 is provided between the chuck table 6 and the rotational drive source. On both sides of the table base 10 in the Y-axis direction, bellows-like stretchable covers 12 are provided. The table base 10 is moved together with the chuck table 6 between a conveying-in/out region A on the front side (one side in the Y-axis direction) and a polishing region B on the rear side (the other side in the Y-axis direction).

A prismatic column section 14 is provided on the rear side of the polishing apparatus 2. A pair of guide rails 16 disposed along the Z-axis direction are fixed on a side surface on the front side of the column section 14. A Z-axis moving plate 18 is slidably attached to the pair of guide rails 16. A nut section (not illustrated) is provided on a side surface on the rear side of the Z-axis moving plate 18, and a ball screw 20 is rotatably connected to the nut section. The ball screw 20 is disposed substantially in parallel to the Z-axis direction. A drive source 22 such as a pulse motor is connected to an upper end portion of the ball screw 20.

The pair of guide rails 16, the Z-axis moving plate 18, the ball screw 20, the drive source 22, and the like constitute a Z-axis direction moving mechanism 24. A support section 26 for fixing a polishing unit 28 thereto is provided on a side surface on the front side of the Z-axis moving plate 18. The polishing unit 28 has a cylindrical spindle housing 30 whose height direction is substantially in parallel to the Z-axis direction. A part of a cylindrical spindle 32 is rotatably accommodated in the spindle housing 30.

A motor 34 is provided at an upper end portion of the spindle 32. A lower end portion of the spindle 32 protrudes downward beyond the spindle housing 30, and an upper surface side of a disk-shaped mount 36 is fixed to the lower end portion of the spindle 32. A disk-shaped polishing tool 40 is mounted to a lower surface side of the mount 36 by using fixtures 38 such as screws. Here, referring to FIG. 4, the polishing tool 40 will be described. The polishing tool 40 has a disk-shaped base 42. An upper surface 42a of the base 42 is fixed to a lower surface of the mount 36.

A plurality of segment polishing pads 44 are fixed to a lower surface (one surface) 42b of the base 42. The segment polishing pad 44 has, for example, a polishing fabric such as a nonwoven fabric, abrasive grains provided in the polishing fabric, and a binder such as varnish for fixing the abrasive grains in the polishing fabric. The abrasive grains are formed of diamond, cerium oxide, silicon oxide, or the like, and have a size on the order of 0.01 μm to 10.0 μm, for example. Note that the segment polishing pad 44 may have a foamed plastic such as foamed polyurethane and abrasive grains fixed in the foamed plastic.

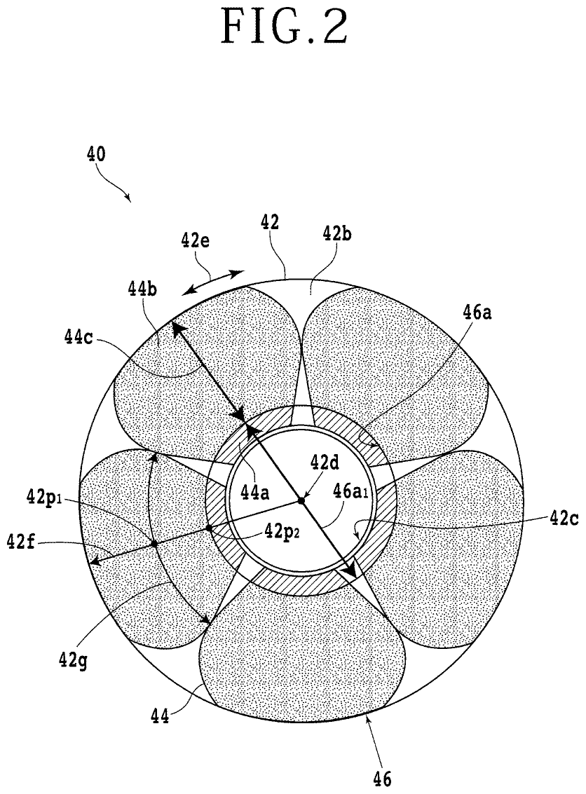

The plurality of segment polishing pads 44 are arranged in an annular pattern in a circumferential direction 42e (see FIG. 2) of the base 42, and constitute a polishing layer 46. A lowermost surface of the polishing layer 46 is formed with a circular opening section 46a. The opening section 46a has a predetermined diameter, and is disposed in a central portion in a diameter direction of the base 42 concentrically with the base 42. Directly above the opening section 46a, a cylindrical opening 42c formed in a central portion in a diameter direction of the base 42, a cylindrical opening 36a formed in a central portion in a diameter direction of the mount 36, and a cylindrical opening 32a formed in a central portion in a diameter direction of the spindle 32 are concentrically disposed (see FIG. 4). The openings 32a, 36a, and 42c function as a supply passage through which basic slurry is supplied in the case of performing wet polishing. In addition, the opening 32a and the like function as a wiring duct where a temperature sensor for measuring the temperature of the wafer 11 and lead wires are disposed in the case of performing dry polishing.

Here, referring to FIG. 2, the configuration of the segment polishing pads 44 will be described. FIG. 2 is a bottom view of the polishing tool 40. In the first embodiment, five segment polishing pads 44 are disposed substantially in rotational symmetry around a center 42d of the lower surface 42b of the base 42. Each segment polishing pad 44 has a shape resembling a cherry petal or a teardrop. The width of the segment polishing pad 44 in a circumferential direction 42e of the lower surface 42b is enlarged from the center 42d to a predetermined position but is reduced from the predetermined position to an outer circumferential end portion, in going outward in a radial direction 42f of the lower surface 42b.

On a circle (see double arrow 42g) that is concentric with the center 42d and that passes through a first position 42p₁ in the radial direction 42f, one segment polishing pad 44 is in contact with two segment polishing pads 44 adjacent in the circumferential direction 42e. In each segment polishing pad 44, an annular thin material section 44a is formed on the inside of a second position 42p₂ located on the inside (that is, on the center 42d side) as compared to the first position 42p₁ in the radial direction 42f. In FIG. 2, oblique lines are applied to the thin material section 44a for the sake of convenience.

A circle that is concentric with the center 42d and that passes through the second position 42p₂ corresponds to the outer shape of the opening section 46a formed in the polishing layer 46. The thin material section 44a becomes gradually thinner in going from the second position 42p₂ toward the center 42d. Note that an inside end portion of the thin material section 44a is located on the outside as compared to the opening 42c in the base 42. The thin material section 44a does not make contact with the wafer 11 when the wafer 11 is polished by the polishing tool 40. Thus, a region on the outside as compared to the thin material section 44a of the segment polishing pad 44 becomes an effective polishing region 44b contributing to polishing of the wafer 11. The effective polishing region 44b in the present embodiment has such a characteristic that the maximum width 44c in the radial direction 42f is smaller than the diameter 46a₁ of the opening section 46a of the polishing layer 46 (that is, maximum width 44c<diameter 46a₁).

Here, returning to FIG. 1, other constituent elements of the polishing apparatus 2 will be described. The polishing apparatus 2 has a control unit 48 that controls operations of the polishing unit 28, the Y-axis direction moving mechanism, the rotational drive source, and the like. The control unit 48 includes a computer including, for example, a processor (processing device) represented by a central processing unit (CPU), a main storage device such as a dynamic random access memory (DRAM), and an auxiliary storage device such as a flash memory. The auxiliary storage device stores software including a predetermined program. By operating the processing device and the like according to the software, the functions of the control unit 48 are realized.

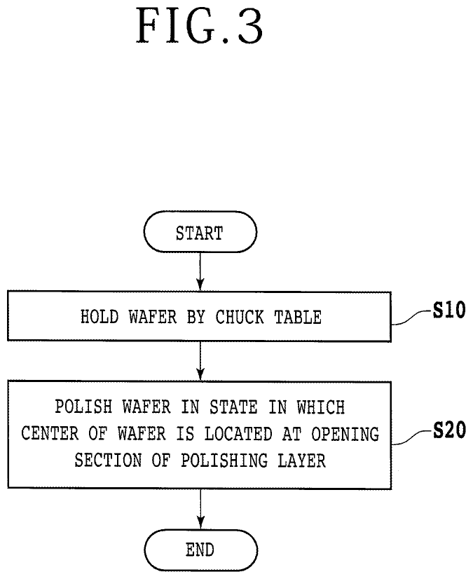

Next, referring to FIGS. 3 to 6, a polishing method of polishing the wafer 11 by use of the polishing apparatus 2 according to the first embodiment will be described. FIG. 3 is a flow chart of a polishing method using the polishing apparatus 2. Note that the diameter of the wafer 11 to be polished in the present embodiment is 300 mm (12 in). First, as depicted in FIG. 4, the front surface 11a side of the wafer unit 15 is held under suction by the holding surface 6a through the protective tape 13 (holding step S10). After the holding step S10, a polishing step S20 of polishing the back surface (one surface) 11b side exposed on the upper side is conducted.

FIG. 4 is a diagram depicting the manner of polishing the wafer 11. In the polishing step S20, first, the chuck table 6 is rotated in a predetermined direction at a first rotational speed (for example, 100 rpm), and the spindle 32 is rotated in a predetermined direction at a second rotational speed (for example, 1,600 rpm). In a state in which the chuck table 6 and the spindle 32 are both rotated, and further, a predetermined load (for example, 300 N) is applied to the wafer 11 by the Z-axis direction moving mechanism 24, the back surface 11b side is polished for a predetermined period of time (for example, 100 sec).

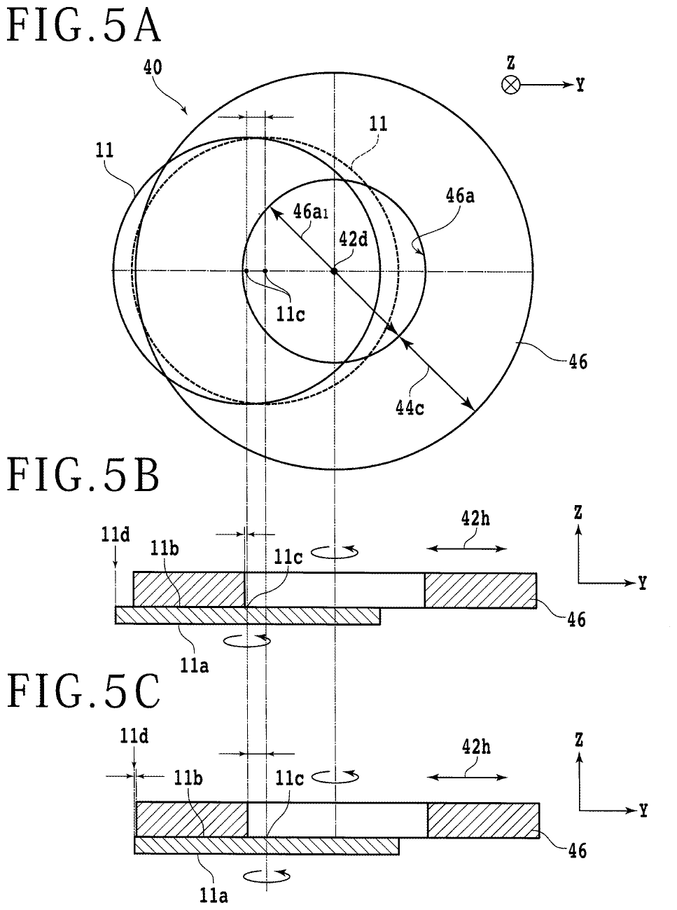

Particularly, in the first embodiment, in a state in which the wafer 11 and the polishing tool 40 are positioned such that the center 11c of the back surface 11b of the wafer 11 is located at the opening section 46a, the back surface 11b side is polished while the polishing tool 40 is rotated. FIG. 5A is a general bottom view depicting the positional relation of the polishing tool 40 and the wafer 11 in the first embodiment. Note that, in FIG. 5A, the polishing layer 46 is depicted in a state of being simplified to an annular region. However, the diameter 46a₁ of the opening section 46a of the polishing layer 46 and the maximum width 44c of the effective polishing region 44b correspond to those in FIG. 2 (that is, maximum width 44c<diameter 46a₁).

In the first embodiment, since the maximum width 44c is 125 mm and the radius of the wafer 11 is 150 mm, the maximum width 44c is smaller than the radius of the wafer 11. Further, since the diameter 46a₁ is 200 mm, the radius of the wafer 11 is smaller than the diameter 46a₁ (that is, maximum width 44c<radius of wafer 11<diameter 46a₁). Note that the outside diameter of each of the base 42 and the polishing layer 46 is 450 mm. FIG. 5B is a general sectional view depicting the wafer 11 polished in the state of being disposed on a front position and the polishing layer 46. The wafer 11 depicted in FIG. 5B corresponds, in terms of position, to the wafer 11 depicted in solid line in FIG. 5A.

In the present embodiment, polishing is conducted such that the center 11c of the back surface 11b is exposed on the opening section 46a, and, thus, when the wafer 11 is located at a front position, the center axis of rotation of the wafer 11 is located slightly on the inner side than an end portion of the opening section 46a. In addition, when the wafer 11 is located at the front position, the center 11c of the back surface 11b is exposed on the opening section 46a, and an end portion (a part of an outer circumferential edge) 11d on the front side of the wafer 11 is not covered with the polishing layer 46 and protrudes from the periphery of the polishing layer 46.

FIG. 5C is a general sectional view of the wafer 11 polished in the state of being disposed at a rear position and the polishing layer 46. The wafer 11 depicted in FIG. 5C corresponds, in terms of position, to the wafer 11 indicated by a broken line in FIG. 5A. Even when the wafer 11 is located at the rear position, the center 11c of the back surface 11b is exposed on the opening section 46a, and the end portion 11d on the front side of the wafer 11 is not covered with the polishing layer 46 and slightly protrudes from the periphery of the polishing layer 46.

In the polishing step S20, the wafer 11 and the polishing tool 40 are relatively moved along a diameter direction 42h of the base 42 passing through the center 11c of the back surface lib, in such a manner that the wafer 11 is reciprocated between the front position (FIG. 5B) and the rear position (FIG. 5C). For example, the wafer 11 is polished while the chuck table 6 is moved along the Y-axis direction at 0.1 mm/s to 0.2 mm/s, by operation of the Y-axis direction moving mechanism. Note that, in the present example in which the maximum width 44c is 125 mm, the radius of the wafer 11 is 150 mm, and the diameter 46a₁ is 200 mm, the wafer 11 is reciprocated with an amplitude of less than 25 mm. Thus, the back surface 11b side can be polished, in a state in which the center 11c is always located at the opening section 46a. Accordingly, excessive polishing in the vicinity of the center 11c of the wafer 11 can be prevented, and generation of a recess in the vicinity of the center 11c can be restrained.

Incidentally, in the case where the end portion 11d on the front side of the wafer 11 does not protrude from the periphery of the polishing layer 46 (that is, where the periphery of the polishing layer 46 protrudes from the end portion lid on the front side of the wafer 11), the polishing layer 46 slightly protrudes downward below the back surface 11b, so that a step is formed at the polishing layer 46. As a result, abnormal load on the polishing layer 46, promotion of deterioration of the polishing layer 46, or the like may be generated. On the other hand, in the present embodiment, even in the case where the wafer 11 is disposed at a rear position (see FIG. 5C), the end portion 11d on the front side of the wafer 11 always protrudes from the periphery of the polishing layer 46, so that a step is not formed at the polishing layer 46. Thus, an abnormal load or deterioration promotion can be prevented.

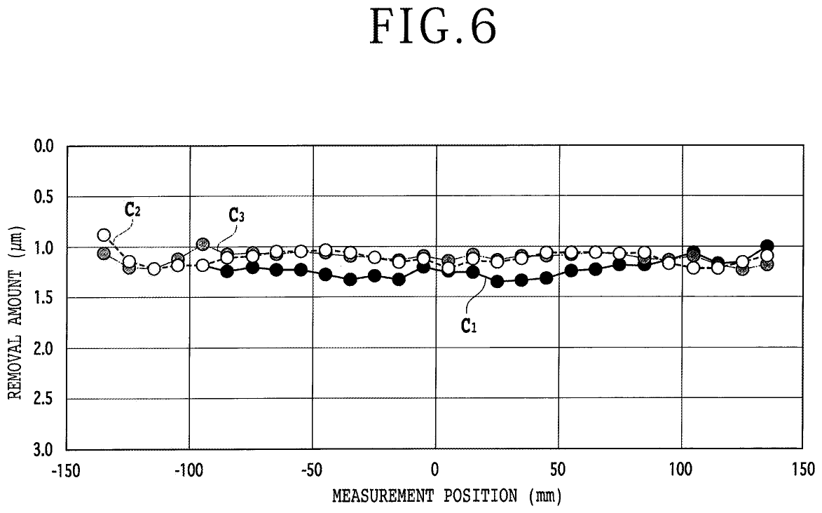

FIG. 6 is a graph depicting the experimental results of measurement of a removal amount of the wafer 11, in the case where the wafer 11 is polished by the polishing method according to the first embodiment. The axis of abscissas represents the measurement position (mm) of the wafer 11 in the case where the center 11c is an origin, and the axis of ordinates represents the removal amount (μm). In this experiment, by use of the polishing apparatus 2 to which the polishing tool 40 is mounted, the back surface 11b sides of three wafers 11 having a diameter of 300 mm (12 in) were sequentially polished. It is to be noted, however, no device was formed on the front surface 11a side of each wafer 11.

Graph C₁, Graph C₂, and Graph C₃ represent polishing results of first, second, and third wafers 11, respectively. The processing conditions were as follows.

Rotational speed of chuck table: 300 rpm

Rotational speed of spindle: 1,500 rpm

Polishing load: 300 N

Reciprocation in Y-axis direction: 0.1 mm/s to 0.2 mm/s

Polishing time: 150 s

Supply of slurry: nil (dry polishing)

In each of Graphs C₁ to C₃, the difference between maximum and minimum of polishing amount was calculated, and the average of the differences was calculated to be 0.364 μm. In other words, comparatively high flatness could be realized. Further, as depicted in FIG. 6, no recess was formed in the vicinity of the center 11c (that is, in the vicinity of the origin).

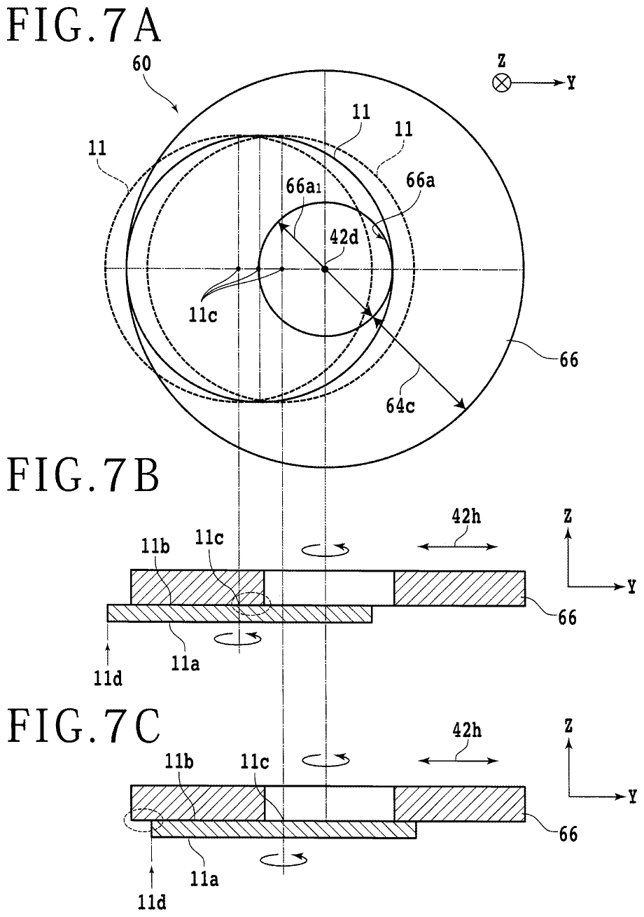

Next, Comparative Example will be described. FIG. 7A is a general bottom view depicting the positional relation of a polishing tool 60 and the wafer 11 in Comparative Example. The polishing tool 60 corresponds to the polishing tool 40 according to the first embodiment, and has a polishing layer 66 that has the same outside diameter (450 mm) as the polishing layer 46. However, a diameter 66a₁ of an opening section 66a of the polishing layer 66 is smaller than the abovementioned diameter 46a₁. The diameter 66a₁ in Comparative Example is 150 mm, and a maximum width 64c of the effective polishing region is also 150 mm.

The wafer 11 depicted in a solid line in FIG. 7A indicates a case where the end portion 11d on the front side of the wafer 11 is overlapped with an end portion on the front side of the polishing layer 66. In this instance, the center 11c of the back surface 11b is located at an end portion of the opening section 66a. On the other hand, the two wafers 11 depicted in broken lines in FIG. 7A indicate the wafer 11 (FIG. 7B) located at a front position and the wafer 11 (FIG. 7C) located at a rear position.

FIG. 7B is a general sectional view of the wafer 11 polished in the state of being disposed at a front position and the polishing layer 66. FIG. 7C is a general sectional view of the wafer 11 polished in the state of being disposed at a rear position and the polishing layer 66. In the case of polishing the wafer 11 having a diameter of 300 mm (12 in) by use of the polishing tool 60, when polishing is conducted while the polishing tool 60 and the wafer 11 are relatively moved in the Y-axis direction, the contact time of the effective polishing region and the vicinity of the center 11c is prolonged, and a recess is generated in the vicinity of the center 11c (see the region surrounded by a broken line in FIG. 7B), as depicted in FIG. 7B.

Further, as depicted in FIG. 7C, the periphery of the polishing layer 66 protrudes from the end portion 11d on the front side of the wafer 11, so that a step is formed at the polishing layer 66. Thus, an abnormal load is exerted on the polishing layer 66, and deterioration of the polishing layer 66 is promoted (see the region surrounded by a broken line in FIG. 7C). On the other hand, as described above, in the first embodiment, the back surface 11b side is polished in a state in which the wafer 11 and the polishing tool 40 are positioned such that the center 11c of the back surface 11b of the wafer 11 is located at the opening section 46a. Thus, excessive polishing in the vicinity of the center 11c of the wafer 11 can be prevented, and generation of a recess in the vicinity of the center 11c can be restrained. Further, in the first embodiment, since the back surface 11b side is polished in a state in which the end portion 11d on the front side of the wafer 11 protrudes from the periphery of the polishing layer 46, no step is formed at the polishing layer 46, and application of an abnormal load to the polishing layer 46 and promotion of deterioration can be prevented.

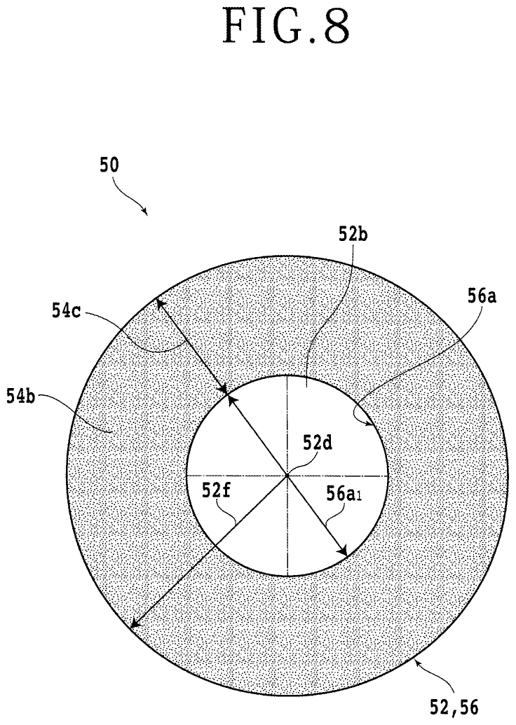

Next, a second embodiment will be described. FIG. 8 is a bottom view of a polishing tool 50 according to a second embodiment. The polishing tool 50 corresponds to the polishing tool 40, and has a base 52 corresponding to the base 42 and a polishing layer 56 corresponding to the polishing layer 46. It is to be noted, however, that the base 52 is disk-shaped and does not have the opening 42c of the base 42, and, in a lower surface (one surface) 52b to which the polishing layer 56 is fixed, a center 52d is not covered with the polishing layer 56 and is exposed.

In addition, the polishing layer 56 does not have a plurality of segment polishing pads 44, but includes a continuous annular polishing pad. The second embodiment differs from the first embodiment in such points, but is the same as the first embodiment in other points. Specifically, a maximum width 54c of an effective polishing region 54b in a radial direction 52f of the base 52 is smaller than a diameter 56a₁ of an opening section 56a of the polishing layer 56 (that is, maximum width 54c<diameter 56a₁). For example, in the case where the radius of the wafer 11 is 150 mm, the maximum width 54c in the radial direction 53f is 125 mm, and the diameter 56a₁ is 200 mm (that is, maximum width 54c<radius of wafer 11<diameter 56a₁).

In the second embodiment as well, excessive polishing in the vicinity of the center 11c of the wafer 11 can be prevented, and generation of a recess in the vicinity of the center 11c can be restrained. Further, a step is not formed at the polishing layer 56, because the back surface 11b is polished in such a manner that the end portion 11d on the front side of the wafer 11 protrudes from the periphery of the polishing layer 56. Therefore, application of an abnormal load to the polishing layer 56 and promotion of deterioration can be prevented. Other than those described above, structures, methods, and the like concerning the embodiments can be carried out with appropriate modifications insofar as the modifications do not depart from the scope of the object of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A polishing method for polishing a wafer by use of a polishing apparatus including a chuck table rotatable in a state of holding the wafer and a polishing unit having a spindle to which a polishing tool for polishing the wafer held by a holding surface of the chuck table is mounted,
the polishing tool having a disk-shaped base and an annular polishing layer that is fixed to one surface of the base and that has an opening section being located at a central portion in a diameter direction of the base and having a predetermined diameter,
a maximum width of an effective polishing region of the polishing layer in a radial direction of the base being smaller than a radius of the wafer and the radius of the wafer being smaller than the diameter of the opening section,
the polishing method comprising:
a holding step of holding the wafer by the holding surface; and
a polishing step of polishing the wafer while rotating the polishing tool around the spindle in a state in which the wafer and the polishing tool are positioned in such a manner that a part of a peripheral edge of the wafer protrudes from a periphery of the polishing layer and that a center of the wafer is located at the opening section of the polishing layer.

2. The polishing method according to claim 1, wherein, in the polishing step, the polishing tool and the wafer are moved relative to each other along a diameter direction of the polishing tool that passes through a center of one surface of the wafer.

3. A polishing tool to be used when polishing a wafer, the polishing tool comprising:
a disk-shaped base; and
an annular polishing layer that is fixed to one surface of the base and that has an opening section being located at a central portion in a diameter direction of the base and having a predetermined diameter,
wherein a maximum width of an effective polishing region of the polishing layer in a radial direction of the base is smaller than the diameter of the opening section.
